(19) United States
(12) Patent Application Publication
(10) Pub. No.: US 2020/0044668 A1
(43) Pub. Date: Feb. 6, 2020

(54) METHOD FOR LDPC DECODING, LDPC DECODER AND STORAGE DEVICE

(71) Applicant: SMARTECH WORLDWIDE LIMITED, Tortola (VG)

(72) Inventor: Yidi Liu, Hong Kong (CN)

(21) Appl. No.: 16/167,529

(22) Filed: Oct. 23, 2018

(30) Foreign Application Priority Data
Aug. 6, 2018 (CN) 201810885859.3

(51) Int. Cl. H03M 13/11; H03M 13/25; H03M 13/00

(52) U.S. Cl. CPC H03M 13/1128; H03M 13/616; H03M 13/118; H03M 13/255

(57) ABSTRACT

A LDPC decoder includes: a coded information receiving circuit, configured to receive coded information and initialize bit information of a variable node; a check node processing circuit, configured to receive first reliability information, and perform check node processing and output second reliability information; a variable node processing circuit, configured to receive the second reliability information, and perform variable node processing to update the bit information of the variable node; a decoding decision circuit, configured to perform a decoding decision for the bit information of the variable node; and a scaling circuit configured to scale the first reliability information transmitted, the second reliability information and the bit information of the variable node.

### CROSS-REFERENCE TO RELATED APPLICATIONS

The present disclosure claims priority to Chinese Patent Application No. 201810885859.3, filed with the Chinese Patent Office on Aug. 6, 2018, titled “METHOD FOR LDPC DECODING, LDPC DECODER AND STORAGE DEVICE”, the entire contents of which are incorporated herein by reference.

### TECHNICAL FIELD

The present disclosure relates to the technical field of LDPC code, and in particular, relates to a method for LDPC decoding, an LDPC decoder and a storage device thereof.

### BACKGROUND

A low-density parity-check (LDPC) code is a good code having excellent performance. The LDPC code pertains to the category of liner block codes, and implements coding and decoding by using a pre-established sparse check matrix and has the performance approaching the Shannon limit.

The LDPC code is greatly advantageous in terms of performance, and is particularly significantly advantageous in case of a long code length. However, coding practice of the LDPC code is very complicated, and a large number of nodes are desired. Therefore, the high cost and difficulties in practice of the hardware circuit restricts its application scope.

For a balance between the difficulties in practice of the decoding circuit and the decoding performance of the LDPC code, the prior art provides many different decoding algorithms and decoding ideas, to address the defects and problems in the aspect of coding and decoding of the LDPC code in terms of practice of the circuit.

However, how to reduce the cost in practice of the hardware circuits for LDPC decoding while ensuring the decoding performance is still a problem to be urgently solved in the practical application of the current LDPC code.

### SUMMARY

An embodiment of the present disclosure provides a method for LPDC decoding. The method includes following steps: initializing, processing several loop iterations, wherein the loop iteration is consist of processing of a check node, processing of a variable node and decoding decision and scaling a first reliability information transmitted from the variable node to the check node and a second reliability information transmitted from the check node to the variable node and bit information of the variable node, in one or more loop iterations.

Another embodiment of the present disclosure provides a LDPC decoder. The LDPC decoder includes a coded information receiving circuit, configured to receive coded information and initialize bit information of a variable node; a check node processing circuit, configured to receive first reliability information, and perform check node processing and output second reliability information; a variable node processing circuit, configured to receive the second reliability information, and perform variable node processing to update the bit information of the variable node; a decoding decision circuit, configured to perform a decoding decision for the bit information of the variable node and a scaling circuit, respectively connected to the variable node processing circuit and the check node processing circuit, and configured to scale the first reliability information transmitted from the variable node to the check node, the second reliability information transmitted from the check node to the variable node and the bit information of the variable node.

Another embodiment of the present disclosure provides a storage device. The storage device includes a plurality of storage units, configured to store LDPC coded information; a controller, configured to read and decode the LDPC coded information from the storage unit, wherein the controller comprises: a coded information receiving circuit, configured to receive LDPC coded information and initialize bit information of a variable node; a check node processing circuit, configured to receive a first reliability information, and perform check node processing and output a second reliability information; a variable node processing circuit, configured to receive the second reliability information, and perform variable node processing to update the bit information of the variable node; a decoding decision circuit, configured to perform a decoding decision for the bit information of the variable node; and a scaling circuit, respectively connected to the variable node processing circuit and the check node processing circuit, and configured to scale the first reliability information transmitted from the variable node to the check node, the second reliability information transmitted from the check node to the variable node and the bit information of the variable node.

### BRIEF DESCRIPTION OF THE DRAWINGS

One or more embodiments are illustrated by way of example, and not by limitation, in the figures of the accompanying drawings, wherein components having the same reference numeral designations represent like components throughout. The drawings are not to scale, unless otherwise disclosed.

FIG. 1 is a schematic diagram of an application scenario of an LDPC code according to an embodiment of the present disclosure;

FIG. 2 is a Tanner diagram of the LDPC code;

FIG. 3 is a flowchart of a method for LDPC decoding;

FIG. 4 is a flowchart of a method for LDPC decoding according to an embodiment of the present disclosure;

FIG. 5 is a flowchart of a method for LDPC decoding according to another embodiment of the present disclosure; and

FIG. 6 is a structural block diagram of an LDPC decoder according to an embodiment of the present disclosure.

### DETAILED DESCRIPTION

For clear description of objectives, technical solutions, and advantages of the present disclosure, the present disclosure is further described in detail below by reference to the embodiments and the accompanying drawings. It should be understood that the specific embodiments described herein are only intended to explain the present disclosure instead of limiting the present disclosure.

The LDPC code may be applied in various information transmission scenarios, for example, channel coding of a wireless radio frequency channel or storage channel coding of a storage device, to improve reliability of information transmission.

FIG. 1 is a schematic diagram of application of an LDPC code in a storage device (for example, a solid hard disk) according to an embodiment of the present disclosure. As illustrated in FIG. 1, the storage device includes an information read-write interface 10, an LDPC coder 20, an LDPC decoder 30, a read-write controller 40 and a plurality of FLASH memory blocks 50.

The information read and write interface 10 is a data interface configured to write or output data streams. Specifically, a corresponding interface form (for example, a USB interface) may be defined according to the actual needs.

The LDPC coder 20 is composed of a corresponding hardware circuit, and is configured to perform LDPC coding for input data input from the information read and write interface 10 according to a predetermined generation matrix and a corresponding coding algorithm. The LDPC decoder 30 is composed of a corresponding hardware circuit according to a predetermined decoding algorithm and check matrix. performs an LDPC decoding operation for coded data read from the FLASH storage block 50.

The read and write controller 40 is connected to a FLASH storage block 50, and is used as a control hub and configured to control the data to be input to the corresponding FLASH storage block 50 or read from a specific location of the FLASH storage block 50 according to a control instruction.

During the practical use, the storage device as illustrated in FIG. 1 may include the following data reading process:

When data is written, data streams are input to the LDPC decoder 20 via the information read and write interface 10. After the LDPC decoder 20 performs the LDPC coding for the input data, the LDPC decoder 20 outputs the coded data to the read and write controller 40. The read and write controller 40 sequentially stores the coded data to the corresponding storage address in the FLASH storage block 50 according to the control instruction.

During data reading, the read and write controller 40 reads the coded data from the corresponding storage address in the FLASH storage block 50 according to the control instruction, and input the read coded data to the LDPC decoder 30. The LDPC decoder 30 performs the LDPC decoding operation for the coded data read from the FLASH storage block 50, and outputs the decoded data via the information read and write interface 10.

Through the above LDPC coding and decoding processes implemented on a storage channel, the reliability of the storage device may effectively improve, and the defect in storage reliability of a memory (for example, an SSD) based on the FLASH technology can be overcome.

Analogously, in a wireless transmission channel, the LDPC code may also be used to improve signal transmission reliability and interference resistant capabilities of the transmitting party and the receiving party, and to reduce external interference during the information transmission process.

For example, an LDPC coder and an LDPC decoder may be respectively arranged between a group of communication modules which establish a wireless communication channel. At an information transmitting end, the communication module performs the LDPC coding for transmitted information via the LDPC coder. At an information receiving end, the communication module performs LDPC decoding for the received coded information via the LDPC decoder.

In a scenario where the LDPC code is applied, it is always expected that the LDPC decoder may be practiced with a small hardware circuit cost while decoding performance is ensured. Hereinafter in combination with the characteristics of the LDPC code, a method for LDPC decoding capable of reducing the hardware cost desired by the LDPC decoder while ensuring the decoding performance is described in detail.

In a check matrix H of the LDPC code, each row represents a check node of the LDPC code, and each column represents a variable node of the LDPC code. For example, in the following check matrix H:

$$H = {[ \begin{matrix}1 & 1 & 0 & 1 & 0 & 1 & 0 \\ 0 & 1 & 1 & 0 & 1 & 0 & 1 \\ 1 & 1 & 1 & 1 & 0 & 1 & 0 \\ 0 & 0 & 0 & 0 & 1 & 1 & 1\end{matrix} ]}^{\begin{matrix}{v}_{1} & {v}_{2} & {v}_{3} & {v}_{4} & {v}_{5} & {v}_{6} & {v}_{7}\end{matrix}} \begin{matrix}{c}_{1} \\ {c}_{2} \\ {c}_{3} \\ {c}_{4}\end{matrix}$$

“0” indicates that no connection (between v3 and c1) is established between the corresponding check node and variable node, and “1” indicates that a connection (between v1 and c1) is established between the corresponding check node and variable node. In each row or each column, the total number of “1s” is referred to as a row weight or a column weight of the check matrix.

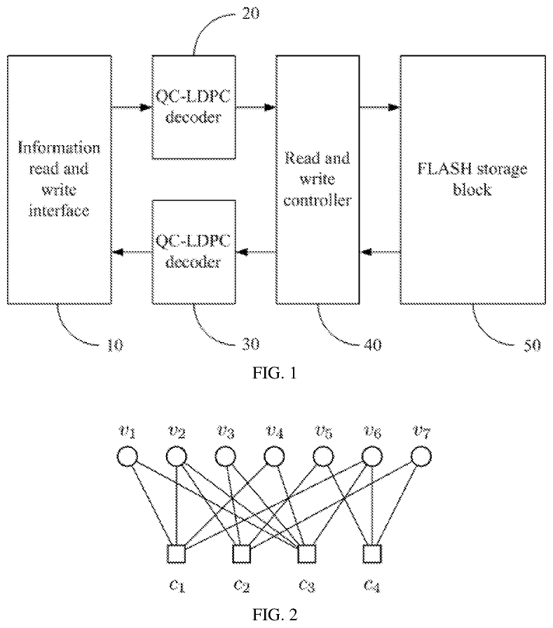

For ease of understanding, the LDPC code may also be represented visually by using a Tannar diagram. As illustrated in FIG. 2, the Tanner graph includes two categories of nodes, check nodes and variable nodes. There are four check nodes, which correspond to the rows in the check matrix H. There are seven variable nodes, which correspond to the columns in the check matrix H. The number of connection lines between the variable nodes and the check nodes is the same as the number of is in the check matrix H.

With reference to the Tanner diagram illustrated in FIG. 2, a soft information transmission method referred to as the “sum-product algorithm” is generally applied for decoding the LDPC code. The basic decoding mode of a typical “sum-product algorithm” is specifically as follows:

Firstly, initialization is performed. Then, bit information (in the first iterative calculation process, the bit information of the current variable node is specified by initial information) of a current variable node, external probability information of a check node connected to each variable node is calculated, and the probability information is transmitted to the check node connected to the variable node.

Each check node calculates, according to the input external probability information, the probability that a check equation is satisfied (assume that the specified information bit and the other information bits have independent probability distributions), and transmits the probability to the variable node (which is also referred to as variable node processing or horizontal processing) connected to the check node.

The variable node may update the bit information of the variable node according to the probability information fed back by the check node (which may also be referred to as check node processing or vertical processing). Each bit of the updated bit information may determine a corresponding decoding result according to a hard decision manner.

Finally, whether the decoding result satisfies the check matrix is judged. If the decoding result satisfies the check matrix, decoded information is output. If the decoding result does not satisfy the check matrix, the variable node processing and the check node processing are repeated, and the bit information of the variable node is re-updated, until a predefined maximum iteration count is reached.

As seen from the above decoding process, although the “sum-product algorithm” is a soft information decoding method which is capable of providing better decoding performance relative to the traditional bit-flipping algorithm and the like “hard decision” manner. However, the variable node processing and the check node processing of the sum-product algorithm include a large number of complicated multiply and divide operations, which causes great difficulties to the practice of the hardware circuit.

Further, the performance of the above sum-product algorithm is improved and the difficulties of practice of the hardware are reduced by representing the probability information transmitted between the variable node and the check node by using a log-likelihood ratio (LLR). Such algorithm is generally referred to as “minimum sum algorithm”.

The update of the external probability information and check probability information transmitted between the variable node and the check node based on the minimum sum algorithm may be represented by the following formula (1), formula (2) and formula (3):

Lᵢ=ΣⱼE_{j,i}+rᵢ (1)

M_{i,j}=Lᵢ−E_{j,i} (2)

E_{j,i}=α(Π_{i′}SIGN{M_{i′,j}})MIN_{i′}{|M_{i′,j}|}) (3)

Lᵢ represents bit information of an i^{th} variable node. In a binary sequence, Lᵢ represents the probability that the i^{th} variable node takes “1” and “0”. In the traditional sum-product algorithm, two pieces of probability information, the probability that the variable node takes “1” and the probability that the variable node takes “0”, is included. After the probability information represented by the log-likelihood ratio (LLR), the above two pieces of probability information are represented as one piece of probability information.

E_{j,i} represents probability information transmitted from a j^{th} check node to the i^{th} variable node. For brevity of description, in this embodiment, “second reliability information” is used to represent the probability that the probability information is transmitted from the check node to the variable node and the probability that a check equation is satisfied. The second reliability information is uninterruptedly iteratively updated in the LDPC decoding process before the decoding is successful or fails.

M_{i,j} represents external probability information transmitted from the i^{th} variable node to the j^{th} check node. For distinctive description, in this embodiment, “first reliability information” is used to represent the external probability information transmitted from the variable node to the check node. Likewise, the first reliability information M_{i,j} is uninterruptedly iteratively updated in the LDPC decoding process before the decoding is successful or fails.

rᵢ represents initial information of the i^{th} variable node. The initial information is an empirical probability of the variable node before the iterative update, and may be an initial value defined according to the actual needs.

α represents an attenuation constant defined according to the actual needs or experience. The attenuation constant is an empirical value which is chosen by a technical personnel.

i′ represents the variable nodes connected to the check node j, besides the i^{th} variable node.

The decoding process based on the minimum sum algorithm is approximately as follows: upon completion of initialization, the first reliability information transmitted from the variable node to the check node is firstly calculated by using formula (2).

Afterwards, based on the first reliability information, the check node calculates the corresponding second reliability information by using formula (3), and feeds back the calculated second reliability information to the variable node. The variable node may update the bit information thereof by using formula (1) based on the second reliability information, and thus completes one integral iterative update processing.

Upon completion of one iterative update, a decoding result of the i^{th} bit is determined in the following hard decision manner; and if Lᵢ≥0, it is determined that the decoding result of the i^{th} bit is 1. Otherwise, it is determined that the decoding result of the i^{th} bit is 0.

Finally, a parity-check is performed for the finally obtained decoding result to judge whether the decoding result satisfies the check equation. If the decoding result satisfies the check equation, it is determined that the decoding is successful and decoded information is output. If the decoding result does not satisfy the check equation, the step of iterative update is performed again until the iterative update count reaches an upper limit value.

As seen from the above LDPC decoding algorithm, in the calculation process based on the “minimum sum algorithm”, all the operations may be implemented by using an adder and a comparator only, which may effectively reduce difficulties in practice of the hardware. Therefore, this algorithm may be extensively applied to hardware design of the decoder.

In some embodiments, by simplifying formula (3), the calculation workload for the “minimum sum algorithm” may be further reduced.

As seen from formula (3), where the number of nodes is great, the calculation workload of MIN_{i′}{|M_{i′,j}|} (which is to find the minimum element in an absolute value set of the second reliability information) is great. In this embodiment, the calculation workload for formula (3) may be reduced in the following way.

For each check node, two fixed values (a first fixed value and a second fixed value) are firstly found as candidate minimum values. In practical operations, two different variables may be respectively defined, and a first minimum value and a second minimum value, and the first fixed value and the second fixed value are respectively assigned to corresponding variables. Afterwards, in the calculation process of formula (3), one of the first fixed value and the second fixed value is directly chosen as the minimum value, and the minimum value is introduced to formula (3) to calculate and acquire the second reliability information.

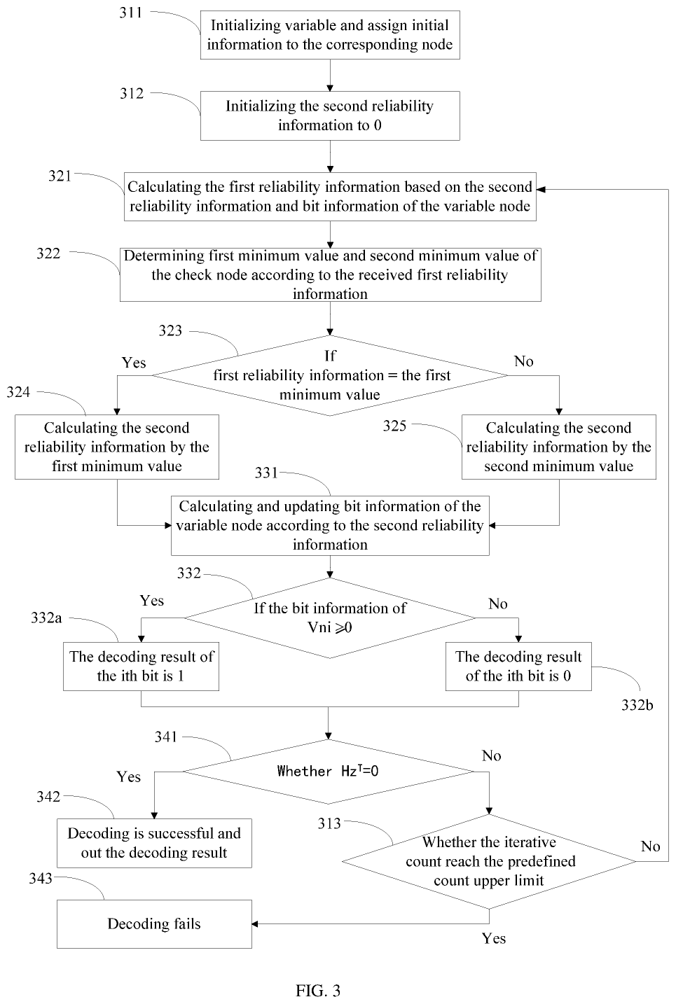

FIG. 3 is a flowchart of a method for implementing the LDPC decoding algorithm according to the above embodiment. As illustrated in FIG. 3, the method includes the following steps:

At an initialization stage:

311. A variable node is initialized, and initial information is assigned to the corresponding node. Assume that the coded information is an i-bit binary sequence, VNᵢ is the i^{th} variable node, and CNⱼ is the j^{th} check node.

312. The second reliability information is initialized to 0.

At a check node processing stage:

321. The first reliability information is calculated based on the current second reliability information and bit information of the variable node.

Through step 321, the external probability information may be updated. It may be understood that in each iterative update process, with update of the second reliability information and the bit information of the variable node, the external probability information is correspondingly iteratively updated.

322. A first minimum value and a second minimum value of the check node are determined according to the received first reliability information.

323. Whether an absolute value of the first reliability information is equal to the first minimum value is judged. If the absolute value of the external probability information is equal to the first minimum value, step 324 is performed; and otherwise, step 325 is performed.

324. The first minimum value is used as a minimum in the external probability information set, and the second reliability information is calculated by using formula (3).

325. The second minimum value is used as a minimum value in the external probability information set, and the second reliability information is calculated by using formula (3).

Based on the external probability information output by the variable node, the check node calculates and updates the second reliability information by using formula (3), and feeds back the updated second reliability information to the variable node connected to the check node.

At a variable node processing stage:

331. The bit information of the variable node is calculated and updated by using formula (1) according to the second reliability information transmitted and fed back by the check node.

332. Whether the bit information of the variable node VNᵢ is greater than or equal to 0 is judged. If the bit information of the variable node VNᵢ is greater than or equal to 0, it is determined that the decoding result of the i^{th} bit is 1 (step 332a). If the bit information of the variable node VNᵢ is not greater than or equal to 0, it is determined that the decoding result of the i^{th} bit is 0 (step 332b).

Step 332 is a hard decision process for determining the decoding result according to the bit information of the variable node. Upon completion of each hard decision process for the bit information, it is considered that one iterative update process is completed, and the iterative update count is increased by 1.

At a decoding decision stage:

341. A parity-check is performed for the acquired decoding result. That is, with respect to the check matrix H of the LDPC code, whether Hz^{T}=0 is judged. If Hz^{T}=0, the parity-check is successful, and step 342 is performed. Otherwise, the parity-check is unsuccessful, and the process returns to the check node processing stage.

After the process returns to the check node processing stage, the first reliability information, the second reliability information and the bit information may be iteratively updated once, and a new decoding result is acquired.

342. It is determined that the decoding is successful, and the decoding result is output.

Generally, the updated decoding result may easier satisfy the check equation. However, to prevent more iterative updates from causing a low decoding efficiency, cycling of the iterative updates needs to be stopped in an appropriate circumstance.

In some embodiments, before the process returns to the check node processing, the following steps may also be included:

313. Whether the iterative update count reaches a predefined count upper limit is judged. If the iterative update count does not reach the predefined count upper limit, the steps of subsequently updating the external probability information and checking the probability information are performed again. If the iterative update count reaches the predefined count upper limit, it is determined that the decoding fails (step 343).

Nevertheless, after the decoding of the current code fails, the receiving end may implement reliable transmission of messages by virtue of a retransmission mechanism or the like, and ensures that the receiving end is capable of receiving accurate transmitted information.

Pseudo codes for describing the method for LDPC decoding as illustrated in FIG. 3 are provided hereinafter. Based on the pseudo codes provided in the embodiment of the present disclosure, a person skilled in the art may implement the LDPC decoding algorithm described by the pseudo codes by using any one computer programming language, and perform the LDPC decoding operations.

| 1 | Iter=0 | | |
|---|---|---|---|
| 2 | for each i in {0, 1, 2, ..., N−1} | | |
| 3 | Lᵢ = rᵢ | | |
| 4 | for each j in Vᵢ | | |
| 5 | E_{j,i} = 0 | | |
| 6 | end for | | |
| 7 | end for | | |
| 8 | | | |
| 9 | for Iter < MAX_ITERATION | | |
| 10 | for each j in {0, 1, 2, ..., M−1} | | |
| 11 | gsⱼ = 1 , min1ⱼ = MAX_V , min2ⱼ = | | |
| | MAX_V | | |
| 12 | for each i in Cⱼ | | |
| 13 | M_{i,j} = Lᵢ − E_{j,i} | | |
| 14 | gsⱼ = gsⱼ * SIGN{M_{i,j}} | | |
| 15 | {min1ⱼ, min2ⱼ} = MIN{min1ⱼ, | | |
| | min2ⱼ, \|M_{i,j}\|} | | |
| 16 | end for | | |
| 17 | end for | | |
| 18 | | | |
| 19 | for each j in {0, 1, 2, ..., M−1} | | |
| 20 | for each i in Cⱼ | | |
| 21 | If \|M_{i,j}\| == min1ⱼ | | |
| 22 | E_{j,i} = α * gsⱼ * SIGN(M_{i,j}) * min2ⱼ | | |
| 23 | else | | |
| 24 | E_{j,i} = α * gsⱼ * SIGN(M_{i,j}) * min1ⱼ | | |
| 25 | end if | | |
| 26 | end for | | |
| 27 | end for | | |
| 28 | | | |
| 29 | for each i in {0, 1, 2, ..., N−1} | | |
| 30 | Lᵢ = rᵢ | | |
| 31 | for each j in Vⱼ | | |
| 32 | Lᵢ = E_{j,i} + Lᵢ | | |
| 33 | | | 1, Lᵢ < 0 |
| | cᵢ = | {open oversize brace} | |
| | | | 0, Lᵢ ≥ 0 |

| | |
|---|---|
| 34 | end for |
| 35 | end for |
| 36 | |
| 37 | if Hz^{T} == 0 |
| 38 | Decode succeeded and finished |
| 39 | else |
| 40 | Iter = Iter + 1 |
| 41 | end if |
| 42 | end for |
| 43 | Decode fail and finished |

Based on the method for LDPC decoding as illustrated in FIG. 3 and the algorithms disclosed by the corresponding pseudo codes, the difficulties in practice of the decoder are reduced in terms of calculation manner, and some multiply and divide operations are avoided.

In some embodiments, the circuit area occupied by the decoder may be further reduced by decreasing a bit width of the decoder.

The bit width of the decoder is the number of bits representing various variables (for example, the external probability information, the check probability information and the bit information) involved in the LDPC decoding algorithm.

It may be understood that a greater bit width (more bits) may represent a greater absolute value of the number. For example, 6 bits may represent a maximum binary number of 2⁶. Nevertheless, the greater the used bit width, the larger the chip area occupied by the hardware circuit. In consideration of the cost, designers always prefer to use a smaller bit width.

However, in design and running of the hardware circuit, generally a sufficiently great bit width is used to represent a variable. On the contrary, if the absolute value of the variable is greater than the maximum value represented by the bit width, data overflow occurs and causes a great impact onto the calculation result.

Therefore, to overcome the problem that the decoding performance is greatly degraded and the error bit ratio (BER) is greatly increased due to occurrence of data overflow, the minimum bit width that may be practically used by the LDPC decoder to represent the bit information is limited. The bit width of the LDPC decoder for representing the bit information should not be less than a minimum value.

For example, assume that a maximum column weight of the check matrix of the LDPC code is 9, and the coded information input to the variable node has 6 bits, the initial information, the first reliability information and the second reliability information all need to be represented by a 6-bit bit width to satisfy the need of data input.

The bit information of the variable node is a sum value acquired by accumulating the initial information to the second reliability information (as seen from formula (1)). As such, an absolute value of the sum value may be relatively greater than the maximum value represented by the bit width and data overflow occurs only when at least a 10-bit bit width is used to represent the bit information.

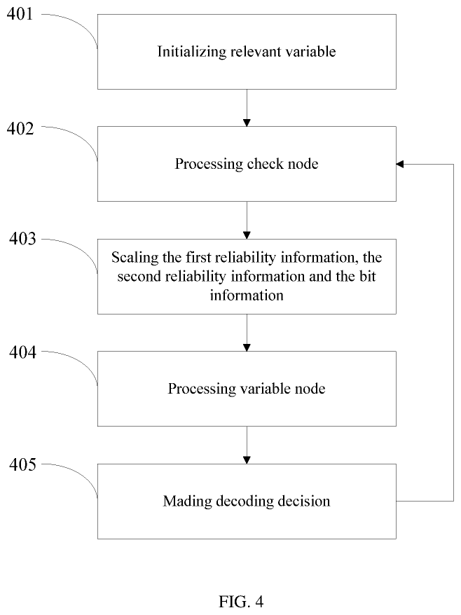

To break through the limitation on the minimum bit width representing the bit information, an embodiment of the present disclosure provides a method for LDPC decoding. In the method for LDPC decoding, by newly added steps, less bit width may be used to represent the bit information while occurrence of data overflow is prevented. FIG. 4 illustrates the Method for LDPC decoding according to the embodiment of the present disclosure. As illustrated in FIG. 4, the Method for LDPC decoding includes the following steps:

401. Relevant variables are initialized. This initialization process implements initial value assignment to the variables involved in the LDPC algorithm that are to be calculated.

402. Check node processing is performed. The check node processing refers to sequentially updating the first reliability information and the second reliability information based on the initialized data. Specifically, calculation may be performed by using the calculation method disclosed in the above embodiment.

403. The first reliability information transmitted from the variable node to the check node, the second reliability information transmitted from the check node to the variable node and the bit information are scaled.

The scaling herein refers to simultaneously decreasing the relevant variables in the LDPC decoding algorithm at the same proportion, to reduce the absolute values of the variables.

In this embodiment, the bit information is acquired by accumulating the initialized initial information. Therefore, scaling of the bit information may also be implemented by scaling the initial information.

404. Variable node processing is performed. The variable node processing refers to updating the bit information of the variable node according to the input second reliability information.

405. A decoding decision is made. The decoding decision refers to making a decision according to the updated bit information to determine a decoding result of each bit, and performing a parity-check for a finally acquired decoding result to determine whether the decoding is successful.

If the parity-check fails and the check matrix is not satisfied, the process may return to step 402 to perform another iteration cycle and re-update the bit information until a predefined iterative update count is reached.

Through scaling the first reliability information, the second reliability information and the bit information (including the initial information), the absolute values of these probability information may be decreased. Therefore, the absolute values of the sum values (that is, the updated bit information) of these reliability information may also corresponding decrease, such that the requirement on the bit width is lowered.

In other words, in design of the hardware circuit, occurrence of data overflow may also be prevented only by representing the bit information using fewer bit widths, such that the original limitation on the bit width is broken through, and the circuit area occupied by the hardware circuit is further reduced. For example, in the above example, after the relevant variables are all scaled, an 8-bit bit width may be used to represent the bit information while the problem of occurrence of data overflow is prevented.

Based on the following reasons, in fact, the scaling of the variables (including the first reliability information, the second reliability information, the bit information and the initial information) involved in the Method for LDPC decoding causes no impact to the calculation result of the LDPC decoding algorithm using the floating-point value.

In one aspect, as seen from formula (3) for updating the second reliability information according to the specification of the present disclosure, in updating the second reliability information, a compare operation needs to be performed for the elements in the set, and calculation is performed after the minimum value is found. The entire LDPC algorithm emphasizes a relative value between the second reliability information.

In another aspect, in the iteration process of the LDPC decoding algorithm, in updating and calculating the variables, the variable-node is pushed to either positive side or negative side instead of middle zero region.

In the embodiment of the present disclosure, the absolute values of the data are decreased by scaling the variables involved in the LDPC decoding algorithm. With the decrease of the absolute value of the bit information, the bit width representing the bit information may be correspondingly reduced to significantly reduce the circuit area occupied by the decoder and thus to break through the limitation on the minimum bit width.

According to the hardware design of the decoder, operations are generally performed based on the fixed-point value. As such, when a variable is scaled by multiplying the variable to a specific scale coefficient, symbol-flipping may frequently occur. For example, if a value is simply scaled to 0.5, −1*0.5=0.

In some embodiments, the scaling may be specifically practiced by shifting rightwards. Shifting rightwards is a good scaling manner which ensures that symbol-flipping does not occur in the scaling down performed by the decoder. A scaling effect may be achieved by shifting rightwards all the involved variables by the same number of bits. For example, a binary value is shifted rightwards by 1 bit, −1 [symbol] 1=−1, and symbol-flipping may not occur.

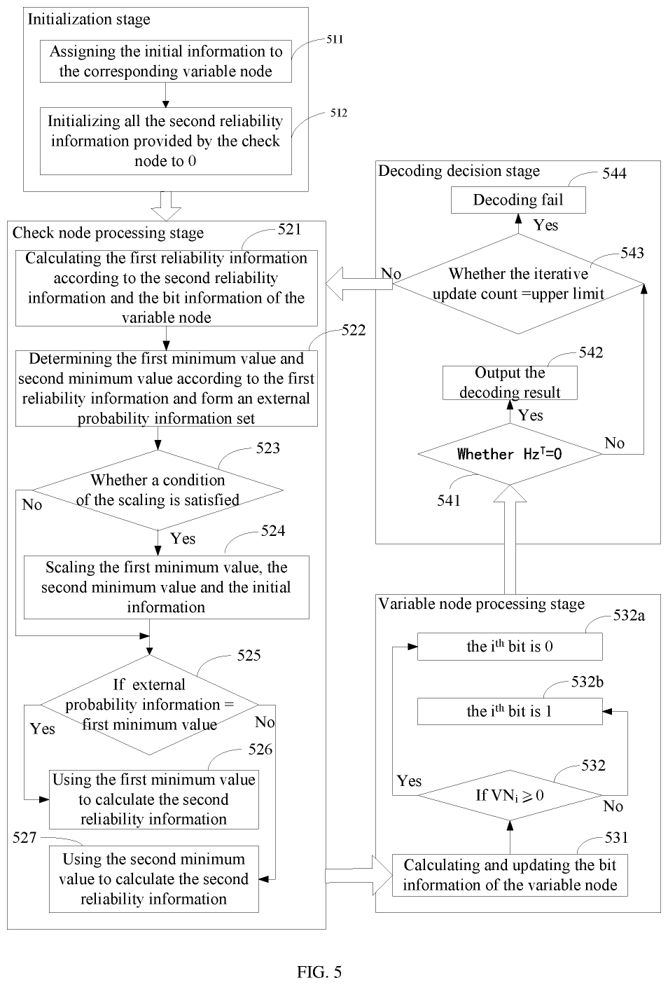

Based on the concept of the LDPC decoding algorithm disclosed in the above embodiment, FIG. 5 is a flowchart of the method for LDPC decoding implementing the scaling according to an embodiment of the present disclosure. As illustrated in FIG. 5, the method includes the following steps:

At an initialization stage:

511. The initial information is assigned to the corresponding variable node as the bit information of the variable node. VNᵢ represents the i^{th} variable node, and CNⱼ represents the j^{th} check node.

512. The second reliability information provided by all the check nodes is all initialized to 0.

At a check node processing stage:

521. The first reliability information transmitted by each variable node i to the check node j connected to the variable node is calculated according to the current second reliability information and the bit information of the variable node.

Step 521 may be referred to as update of the first reliability information. In each iteration process, with variations of the bit information, the first reliability information may correspondingly vary to implement the iterative update.

522. A first minimum value and a second minimum value of each check node j are determined according to the current first reliability information, and the first minimum value, the second minimum value and the external probability information are combined to form an external probability information set.

The first minimum value and the second minimum value are both fixed values found in advance by each check node as candidates of the minimum value for calculation of the second reliability information.

523. Whether a condition of the scaling is satisfied is judged. If condition of the scaling is satisfied, step 424 is performed; and otherwise, step 524 is skipped over and step 525 is performed.

The scaling causes no impact to the calculation result of the LDPC decoding algorithm in calculation by using the floating-point value. However, with respect to the fixed-point value, the scaling still causes a loss of the accuracy, and particularly, in the case where the absolute value is small, the impact caused by the scaling is obvious.

Therefore, to ensure the decoding performance of the LDPC decoding algorithm, some specific scaling conditions may be defined according to the actual needs, the scaling is selectively performed in a part of the iterative updates instead of performing the scaling in the entire LDPC decoding process.

In some embodiments, the scaling condition may be specifically defined as whether the absolute value of the current bit information is less than a predefined threshold. It is considered that the scaling condition is satisfied only when the absolute value of the bit information is greater than or equal to the predefined threshold.

The predetermined threshold is a critical value that is used to ensure that the scaling causes no impact to normal use of the decoder. The predefined threshold may be determined by a person skilled in the art by experimental means according to a plurality of factors (for example, a requirement on the performance of the decoder).

524. The first minimum value, the second minimum value and the initial information are scaled.

In this embodiment, the second reliability information is acquired based on the predefined first minimum value or second minimum value. Therefore, by scaling the first minimum value, the second minimum value and the initial coded information, the values of the variables involved in the LDPC decoding algorithm according to the embodiment of the present disclosure may be scaled.

525. Whether an absolute value of the external probability information is equal to the first minimum value is judged. If the absolute value of the external probability information is equal to the first minimum value, step 526 is performed; and otherwise, step 527 is performed.

526. The first minimum value is used as a minimum value in the external probability information set, and the second reliability information is calculated by using formula (3).

527. The second minimum value is used as a minimum value in the external probability information set, and the second reliability information is calculated by using formula (3).

Step 527 is an update process in which the check node calculates and updates the second reliability information provided for the variable node by using formula (3) based on the updated external probability information.

At a variable node processing stage:

531. The bit information of the variable node is calculated and updated by using formula (1) according to the second reliability information input by the check node.

532. Whether the updated bit information of the variable node VNᵢ is greater than or equal to 0 is judged. If the updated bit information of the variable node VNᵢ is greater than or equal to 0, it is determined that a decoding result of the i^{th} bit is 1 (step 532a); and otherwise, it is determined that the decoding result of the i^{th} bit is 0 (step 532b).

At a decoding decision stage:

541. A parity-check is performed for the acquired decoding result (a multi-bit binary sequence). That is, whether Hz^{T}=0 is judged. If Hz^{T}=0, the parity-check is successful, and step 542 is performed. Otherwise, the parity-check is unsuccessful, and the process returns to the check node processing stage.

542. It is determined that the decoding is successful, and the decoding result is output.

After the process returns to the check node processing stage, another iteration may be performed to update the bit information of the variable node, so as to improve the probability that the decoding is successful. Generally, for the sake of preventing the problem that the decoding efficiency is low due to excessive iterations, before the process returns to the check node processing stage, the following steps may be included:

543. Whether the iterative update count reaches a predefined count upper limit is judged. If the iterative update count reaches the predefined count upper limit, the subsequent variable node processing step and check node processing step are performed to update the bit information. If the iterative update count does not reach the predefined count upper limit, it is determined that the decoding fails (step 544).

Pseudo codes for describing the Method for LDPC decoding as illustrated in FIG. 5 are provided hereinafter. Based on the pseudo codes provided in the embodiment of the present disclosure, a person skilled in the art may implement the LDPC decoding algorithm described by the pseudo codes by using any one computer programming language, and perform the LDPC decoding operations.

| 1 | Iter=0 | | |
|---|---|---|---|
| 2 | for each i in {0, 1, 2, ..., N−1} | | |
| 3 | Lᵢ = rᵢ | | |
| 4 | for each j in Vᵢ | | |
| 5 | E_{j,i} = 0 | | |
| 6 | end for | | |
| 7 | end for | | |
| 8 | | | |
| 9 | for Iter < MAX_ITERATION | | |
| 10 | for each j in {0, 1, 2, ..., M−1} | | |
| 11 | gsⱼ = 1 , min1ⱼ = MAX_V , min2ⱼ = | | |
| | MAX_V | | |
| 12 | for each i in Cⱼ | | |
| 13 | M_{i,j} = Lᵢ − E_{j,i} | | |
| 14 | gsⱼ = gsⱼ * SIGN{M_{i,j}} | | |
| 15 | {min1ⱼ, min2ⱼ} = MIN{min1ⱼ, | | |
| | min2ⱼ, \|M_{i,j}\|} | | |
| 16 | end for | | |
| | min1ⱼ = α * min1ⱼ | | |
| | min2ⱼ = α * min2ⱼ | | |
| 17 | end for | | |
| 18 | | | |
| 19 | if scaling_monitor( ) = TURE | | |
| 20 | for each j in {0, 1, 2, ..., M−1} | | |
| 21 | min1ⱼ = scalling(min1ⱼ) | | |
| 22 | min2ⱼ = scalling(min2ⱼ) | | |
| 23 | end for | | |
| 24 | for each i in {0, 1, 2, ..., N−1} | | |
| 25 | rᵢ = scalling(rᵢ) | | |
| 26 | end for | | |
| 27 | end if | | |
| 28 | | | |
| 29 | for each j in {0, 1, 2, ..., M−1} | | |
| 30 | for each i in Cⱼ | | |
| 31 | If \|M_{i,j}\| == min1ⱼ | | |
| 32 | E_{j,i} = gsⱼ * SIGN(M_{i,j}) * min2ⱼ | | |
| 33 | else | | |
| 34 | E_{j,i} = gsⱼ * SIGN(M_{i,j}) * min1ⱼ | | |
| 35 | end if | | |
| 36 | end for | | |
| 37 | end for | | |
| 38 | | | |
| 39 | for each i in {0, 1, 2, ..., N−1} | | |
| 40 | Lᵢ = rᵢ | | |
| 41 | for each j in Vⱼ | | |
| 42 | Lᵢ = E_{j,i} + Lᵢ | | |
| 43 | | | 1, Lᵢ < 0 |
| | cᵢ = | {open oversize brace} | |
| | | | 0, Lᵢ ≥ 0 |

| | |
|---|---|
| 44 | end for |
| 45 | end for |
| 46 | |
| 47 | if Hz^{T} == 0 |
| 48 | Decode succeeded and finished |
| 49 | else |
| 50 | Iter = Iter + 1 |
| 51 | end if |
| 52 | end for |
| 53 | Decode fail and finished |

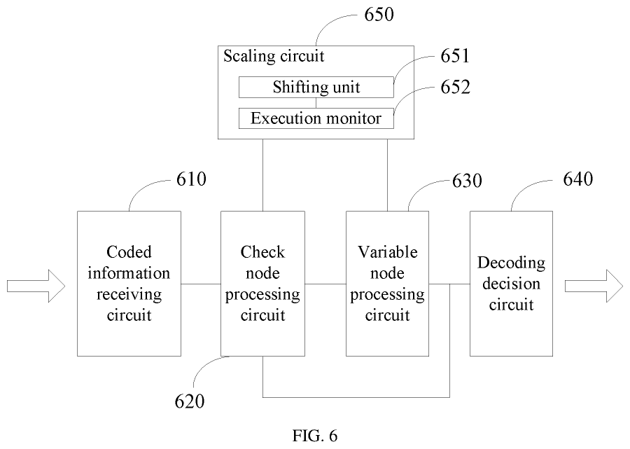

An embodiment of the present disclosure further provides an LDPC decoder for implementing the Method for LDPC decoding as illustrated in FIG. 5. The LDPC decoder employs the scaling manner, the bit information may be represented by a smaller bit width relative to the conventionally used decoder. The LDPC decoder occupies a smaller chip circuit area. FIG. 6 is a structural block diagram of the LDPC decoder according to the embodiment of the present disclosure.

As illustrated in FIG. 6, the decoder may include: a coded information receiving circuit 610, a check node processing circuit 620, a variable node processing circuit 630, a decoding decision circuit 640 and a scaling circuit 650.

The coded information receiving circuit 610 is configured to receive coded information having a predefined code length, and initialize bit information of a variable node and other variables to be used.

The variable node processing circuit 620 is connected to the coded information receiving circuit 610, and configured to perform the variable node processing for each variable node to update first reliability information and second reliability information. The variable node processing circuit 630 is connected to the check node processing circuit 520, and configured to perform check node processing to update bit information of the variable node according to the second reliability information.

The decoding decision circuit 640 is configured to perform a decision for the bit information to determine a decoding result of each bit and judge whether the decoding result satisfies a check matrix.

If it is judged that the decoding result satisfies the check matrix, decoded information may be directly output to complete decoding of the current codeword. If it is judged that the decoding result does not satisfy the check matrix, the process returns again to the check node processing circuit 620 and the variable node processing circuit 630 to update the bit information to perform a next decoding decision.

The scaling circuit 650 is respectively connected to the check node processing circuit and the variable node processing circuit, and configured to scale relevant variables (including the first reliability information transmitted from the variable node to the check node, the second reliability information transmitted from the check node to the variable node, the bit information of the variable node, and initial information for initialization and the like) in the LDPC decoding process, to reduce absolute values of these variables.

In some embodiments, to prevent the problem of symbol-flipping in the scaling, the scaling circuit may include a shifting unit 651, and the scaling is performed by using the shifting unit 651.

The shifting unit 651 is configured to perform a perform a rightward shift operation for the values to be scaled (including the first reliability information, the second reliability information, the bit information and the initial information), such that these values are scaled while it is ensured that symbol-flipping does not occur.

In some other embodiments, the scaling still causes some impacts to the calculation result of the LDPC decoding algorithm in some specific environments (for example, when the values are smaller). Therefore, to mitigate the impacts caused by the scaling to the LDPC decoding performance, an execution monitor 552 may be further arranged, and the scaling may be selectively performed in a part of the iterative updates.

As illustrated in FIG. 5, the execution monitor 652 is connected to the shifting unit 651, and configured to judge whether the current bit information of the variable node is greater than a predefined threshold, and enable the shifting unit 651 to perform the rightward shift operation for the first reliability information, the second reliability information, the bit information and the initial information if the current bit information of the variable node is greater than the predefined threshold.

In this way, the accuracy loss which is caused by scaling the variables with small absolute values, can be prevented.

It should be noted that in the embodiment of the present disclosure, the hardware circuits in the LDPC decoder are only described based on functional (for example, the coded information receiving circuit 610, the check node processing circuit 620, the variable node processing circuit 630, the decoding decision circuit 640 and the scaling down circuit 650). A person skilled in the art may select, adjust or combine the commonly used circuit structures in the art to practice circuit structures for implementing one or a plurality of functions in the above embodiments according to the functions to be implemented by the hardware circuits disclosed in the embodiment of the present disclosure.

Professional personnel should be further aware that with reference to the embodiments of the present application disclosed herein, various exemplary LDPC code decoding steps may be implemented in the form of electronic hardware, computer software or a combination thereof. To clearly describe interchangeability between the hardware and software, the above description has generally illustrates the compositions and steps of the various example according to the functions. Whether such functions are implemented in the form of software or hardware depends on the specific application and the design restrictions applied to the entire system.

Professional technical personnel may implement the described functions by using different methods for each specific application. However, such implementation shall not be deemed as going beyond the scope of the present disclosure. The computer software program may be stored in a computer readable storage medium, wherein the computer software program, when being executed, may perform the steps and processes according to the above method embodiments. The storage medium may be any medium capable of storing program codes, such as read-only memory (ROM), a random access memory (RAM), a magnetic disk, or a compact disc-read only memory (CD-ROM).

Described above are exemplary embodiments of the present disclosure, but are not intended to limit the scope of the present disclosure. Any equivalent structure or equivalent process variation made based on the specification and drawings of the present disclosure, which is directly or indirectly applied in other related technical fields, fall within the scope of the present disclosure.

What is claimed is:

1. A method for LPDC decoding, comprising:
initializing,
processing several loop iterations, wherein the loop iteration is consist of processing of a check node, processing of a variable node and decoding decision;
scaling a first reliability information transmitted from the variable node to the check node and a second reliability information transmitted from the check node to the variable node and bit information of the variable node, in one or more loop iterations.

2. The method according to claim 1, scaling the first reliability information, the second reliability information and the bit information in a shifting manner.

3. The method according to claim 1, further comprising:
determining whether the loop iteration satisfies a predetermined execution condition; and
scaling the first reliability information, the second reliability information and the bit information if the predetermined execution condition is satisfied.

4. The method according to claim 3, wherein the determining whether the loop iteration satisfies a predetermined execution condition comprises:
determining whether the bit information of the variable information is less than a predetermined threshold;
determining that the loop iteration satisfies the predetermined execution condition if the bit information of the variable information is less than the predetermined threshold; and
determining that the loop iteration does not satisfy the predetermined execution condition if the bit information of the variable information is not less than the predetermined threshold.

5. The method according to claim 1, wherein the processing of the check node comprises:
calculating the second reliability information according to the received first reliability information; and
transmitting the second reliability information to the corresponding variable node.

6. The method according to claim 5, wherein the processing of the variable node comprises:
updating the bit information of the variable node according to the received second reliability information.

7. The method according to claim 6, wherein the calculating the second reliability information according to the received first reliability information comprises:
at each check node, calculating the second reliability information through following formula:
E_{j,i}=α(Π_{i′}SIGN{M_{i′,j}})MIN_{i′}{|M_{i′,j}|})
wherein E_{j,i} represents second reliability information transmitted from a j^{th} check node to an i^{th} variable node, i′ represents a variable node among all the variable nodes connected to the j^{th} check node except the i^{th} variable node, M_{i′,j} represents first reliability information transmitted from an i^{'th} variable node to the j^{th} check node.

8. The method according to claim 7, wherein the determining the second reliability information according to the first reliability information comprises:
determining a first minimum value and a second minimum value in all the first reliability information transmitted to the j^{th} check node according to the current first reliability information; and
choosing the first minimum value or the second minimum value as a minimum value, and calculating the second reliability information.

9. A LDPC decoder, comprising:
a coded information receiving circuit, configured to receive coded information and initialize bit information of a variable node;
a check node processing circuit, configured to receive first reliability information, and perform check node processing and output second reliability information;
a variable node processing circuit, configured to receive the second reliability information, and perform variable node processing to update the bit information of the variable node;
a decoding decision circuit, configured to perform a decoding decision for the bit information of the variable node; and
a scaling circuit, respectively connected to the variable node processing circuit and the check node processing circuit, and configured to scale the first reliability information transmitted from the variable node to the check node, the second reliability information transmitted from the check node to the variable node and the bit information of the variable node.

10. The LDPC decoder according to claim 9, wherein the scaling circuit comprises a shifting unit configured to perform a rightward shift operation for the first reliability information, the second reliability information and the bit information.

11. The LDPC decoder according to claim 10, wherein the scaling circuit further comprises an execution monitor coupled to the shifting unit, configured to determine whether the bit information of the variable node is greater than a predefined threshold; and
enable the shifting unit to perform the rightward shift operation for the first reliability information, the second reliability information and the bit information if the bit information of the variable node is greater than the predefined threshold.

12. A storage device, comprising:
a plurality of storage units, configured to store LDPC coded information;
a controller, configured to read and decode the LDPC coded information from the storage unit, wherein the controller comprises:
a coded information receiving circuit, configured to receive LDPC coded information and initialize bit information of a variable node;
a check node processing circuit, configured to receive a first reliability information, and perform check node processing and output a second reliability information;
a variable node processing circuit, configured to receive the second reliability information, and perform variable node processing to update the bit information of the variable node;
a decoding decision circuit, configured to perform a decoding decision for the bit information of the variable node; and
a scaling circuit, respectively connected to the variable node processing circuit and the check node processing circuit, and configured to scale the first reliability information transmitted from the variable node to the check node, the second reliability information transmitted from the check node to the variable node and the bit information of the variable node.

13. The storage device according to claim 12, wherein the scaling circuit comprises a shifting unit configured to perform a rightward shift operation for the first reliability information, the second reliability information and the bit information.

14. The storage device according to claim 13, wherein the scaling circuit further comprises an execution monitor coupled to the shifting unit, and configured to determine whether the bit information of the variable node is greater than a predefined threshold; and
enable the shifting unit to perform the rightward shift operation for the first reliability information, the second reliability information and the bit information if the bit information of the variable node is greater than the predefined threshold.
